(19) United States
(12) Patent Application Publication
(10) Pub. No.: US 2016/0013178 A1
(43) Pub. Date: Jan. 14, 2016

(54) ELECTROSTATIC DISCHARGE PROTECTION DEVICE AND SEMICONDUCTOR DEVICE INCLUDING THE SAME

(71) Applicant: SAMSUNG ELECTRONICS CO., LTD., Suwon-si (KR)

(72) Inventor: Sung-jun SONG, Hwaseong-si (KR)

(73) Assignee: SAMSUNG ELECTRONICS CO., LTD., Suwon-si (KR)

(21) Appl. No.: 14/710,709

(22) Filed: May 13, 2015

(30) Foreign Application Priority Data
Jul. 14, 2014 (KR) 10-2014-0088455

(51) Int. Cl. H01L 27/02; H01L 29/78

(52) U.S. Cl. CPC H01L 27/0266; H01L 29/78

(57) ABSTRACT

An electrostatic discharge (ESD) protection device is provided. The electrostatic discharge (ESD) protection device includes: a semiconductor substrate of a first conductive type; a gate formed on the semiconductor substrate; a first well which is disposed at a first side of the substrate under the gate and comprises a first drain of a second conductive type in at least a portion of the first well; a second well which is disposed at a second side of the substrate under the gate and comprises a first source of the second conductive type in at least a portion of the second well; and a deep well of the second conductive type, formed under the first and second wells.

### CROSS-REFERENCE TO RELATED APPLICATIONS

This application claims priority from Korean Patent Application No. 10-2014-0088455, filed on Jul. 14, 2014, in the Korean Intellectual Property Office, the disclosure of which is incorporated herein in its entirety by reference.

### BACKGROUND

Apparatuses consistent with exemplary embodiments of the inventive concept relate to an electrostatic discharge (ESD) protection device and a semiconductor device including the ESD protection device, and more particularly, to an ESD protection device having an improved tolerance and a semiconductor device including the improved ESD protection device.

ESD protection devices are devices for preventing the destruction or deterioration of products due to a surge. When a semiconductor integrated circuit contacts a charged human body or machine, a surge current having a large amount of energy may flow into an internal circuit of the semiconductor integrated circuit while a surge charged in the human body or machine is discharged into the internal circuit through an input/output pad via an external pin of the semiconductor integrated circuit, and thus, the semiconductor integrated circuit may be damaged. In addition, a surge charged in the inside of the semiconductor integrated circuit may be discharged to the outside through a machine by contact with the machine, and thus, a surge current may flow into an internal circuit of the semiconductor integrated circuit, thereby damaging the semiconductor integrated circuit.

### SUMMARY

The exemplary embodiments of the inventive concept provide an electrostatic discharge (ESD) protection device having an improved tolerance.

The exemplary embodiments of the inventive concept also provide a semiconductor device including the ESD protection device.

According to an exemplary embodiment of the inventive concept, there is provided an ESD protection device which may include: a semiconductor substrate of a first conductive type; a gate formed on the semiconductor substrate; a first well which is disposed at a first side of the substrate under the gate and comprises a first drain of a second conductive type in at least a portion of the first well; a second well which is disposed at a second side of the substrate under the gate and comprises a first source of the second conductive type in at least a portion of the second well; and a deep well of the second conductive type, formed under the first and second wells.

The first and second wells may be the second and first conductive types, respectively.

The first conductive type may be one selected from an N type and a P type, and the second conductive type may be the other selected from the N type and the P type.

An impurity doping concentration of the first drain may be higher than that of the first well.

An impurity doping concentration of the first source may be higher than that of the second well.

The ESD protection device may further include a second drain of the second conductive type, formed in the semiconductor substrate.

The first drain and the second drain may be electrically connected to at least one of a power supply voltage pad and an input/output pad.

The ESD protection device may further include a third well of the second conductive type, wherein the second drain is formed in at least a portion of the third well, and an impurity doping concentration of the second drain is higher than that of the third well.

The ESD protection device may further include a second source of the first conductive type, formed in the semiconductor substrate.

The first source and the second source may be electrically connected to a ground voltage pad.

The ESD protection device may further include a fourth well of the first conductive type, wherein the second source is formed in at least a portion of the fourth well, and an impurity doping concentration of the second source is higher than that of the fourth well.

The ESD protection device may further include: a first parasitic transistor formed in the semiconductor substrate, the first parasitic transistor including the first drain and the first source as electrodes; and a second parasitic transistor formed in the semiconductor substrate, the second parasitic transistor including the first source and the deep well as electrodes, wherein a distance between the first drain and the first source is a first interval, a first triggering voltage of the first parasitic transistor is set based on the first interval, a distance between the first source and the deep well is a second interval, a second triggering voltage of the second parasitic transistor is set based on the second interval, and the first triggering voltage is equal or substantially equal to the second triggering voltage.

According to another exemplary embodiment of the inventive concept, there is provided a semiconductor device which may include an ESD protection circuit and an internal circuit, wherein the ESD protection circuit may include: a semiconductor substrate of a first conductive type; a gate formed on the semiconductor substrate; a first well positioned at a first side of the semiconductor substrate under the gate, wherein a first drain of a second conductive type is formed in at least a portion of the first well; a second well positioned at a second side of the semiconductor substrate under the gate, wherein a first source of the second conductive type is formed in at least a portion of the second well; and a deep well of the second conductive type, formed under the first and second wells.

The first conductive type may be one of an N type and a P type, and the second conductive type may be the other of the N type and the P type.

The first drain may be electrically connected to a power supply voltage pad, and the first source may be connected to a ground voltage pad.

The first drain may be electrically connected to an input/output pad, and the first source may be connected to a ground voltage pad.

The semiconductor device may further include a pad portion including a ground voltage pad, a power supply voltage pad, and an input/output pad, wherein the pad portion is electrically connected to the internal circuit, and when a surge is applied to the pad portion, the pad portion and the ESD protection circuit are electrically connected to each other to form a current discharge path of the surge.

According to still another exemplary embodiment of the inventive concept, there is provided a semiconductor device which may include an ESD protection circuit and an internal circuit, wherein the ESD protection circuit may include: a first ESD protection transistor using a first drain of a second conductive type, a first source of the second conductive type, and a first well of the second conductive type, which are formed in a semiconductor substrate of a first conductive type; and a second ESD protection transistor using the first source, a second well of the first conductive type, and a deep well of the second conductive type.

A first triggering voltage of the first ESD protection transistor may be equal or substantially equal to a second triggering voltage of the second ESD protection transistor.

A surge current may flow through a first path and a second path, wherein the first path includes the first drain of the first ESD protection transistor as a first electrode and the first source as a second electrode, and the second path includes the deep well of the second ESD protection transistor as a third electrode and the first source as a fourth electrode.

According to still another exemplary embodiment of the inventive concept, there is provided semiconductor device which may include an electrostatic discharge (ESD) protection device and an internal circuit, wherein the EST protection device may include: a first conductive type substrate; a second conductive type deep well; at least one first conductive type well and at least one second conductive type well disposed above the second conductive type deep well; at least one source formed in the at least one first conductive type well, respectively, and at least one drain formed in the at least one second conductive type well, respectively; an input/output (I/O) terminal which connects the internal circuit and the first and second to input or output a signal from or to the outside of the internal circuit; a power supply voltage terminal; and a ground voltage terminal.

### BRIEF DESCRIPTION OF THE DRAWINGS

Exemplary embodiments of the inventive concept will be more clearly understood from the following detailed description taken in conjunction with the accompanying drawings, in which:

FIG. 1 is a block diagram of a semiconductor device, according to an exemplary embodiment of the inventive concept;

FIG. 2 is a block diagram specifically illustrating an electrostatic discharge (ESD) protection device of a semiconductor device, according to an exemplary embodiment of the inventive concept;

FIG. 3 is a cross-sectional view of an ESD protection device, according to an exemplary embodiment of the inventive concept;

FIG. 4 is a cross-sectional view of an ESD protection device, according to another exemplary embodiment of the inventive concept;

FIG. 5 is a cross-sectional view of an ESD protection device, according to another exemplary embodiment of the inventive concept;

FIG. 6 is a cross-sectional view of an ESD protection device, according to another exemplary embodiment of the inventive concept;

FIG. 7 is a cross-sectional view of an ESD protection device, according to another exemplary embodiment of the inventive concept;

FIG. 8 is a block diagram of a semiconductor internal circuit using an ESD protection device, according to an exemplary embodiment of the inventive concept;

FIG. 9 is a block diagram of a semiconductor internal circuit using an ESD protection device, according to another exemplary embodiment of the inventive concept;

FIG. 10 is a graph showing a comparison between current-voltage characteristics of ESD protection devices according to exemplary embodiments of the inventive concept and current-voltage characteristics of conventional ESD protection devices;

FIG. 11 is a flowchart of a method of forming an ESD protection device, according to an exemplary embodiment of the inventive concept;

FIG. 12 is a block diagram of a memory card including a semiconductor integrated circuit, according to an exemplary embodiment of the inventive concept;

FIG. 13 is a block diagram of a computing system including a semiconductor integrated circuit, according to an exemplary embodiment of the inventive concept;

FIG. 14 is a top view of a solid state drive (SSD) device to which a semiconductor package, which includes an ESD protection circuit including at least one ESD protection device according to an exemplary embodiment of the inventive concept, is applied; and

FIG. 15 is a perspective view of an electronic device to which a semiconductor package, which includes an ESD protection circuit including at least one ESD protection device according to an exemplary embodiment of the inventive concept, is applied.

### DETAILED DESCRIPTION OF THE EXEMPLARY EMBODIMENTS

The inventive concept will now be described more fully with reference to the accompanying drawings, in which exemplary embodiments of the inventive concept are shown. The inventive concept may, however, be embodied in many different forms, and should not be construed as being limited to the embodiments set forth herein; rather, these embodiments are provided so that this disclosure will be thorough and complete, and will fully convey the inventive concept to those of ordinary skill in the art. Thus, the inventive concept may include all revisions, equivalents, or substitutions which are included in the concept and the technical scope related to the invention Like reference numerals in the drawings denote like elements. In the drawings, the dimension of structures may be exaggerated for clarity.

Furthermore, all examples and conditional language recited herein are to be construed as being without limitation to such specifically recited examples and conditions. Throughout the specification, a singular form may include plural forms, unless there is a particular description contrary thereto. Also, terms such as “comprise” or “comprising” are used to specify existence of a recited form, a number, a process, an operation, a component, and/or groups thereof, not excluding the existence of one or more other recited forms, one or more other numbers, one or more other processes, one or more other operations, one or more other components and/or groups thereof.

While such terms as “first”, “second”, etc., may be used to describe various components, such components must not be limited to the above terms. The above terms are used only to distinguish one component from another. For example, a first component may be named as a second component, and similarly the second component may be named as the first component, without departing from the scope of the inventive concept.

Unless expressly described otherwise, all terms including descriptive or technical terms which are used herein should be construed as having meanings that are obvious to one of ordinary skill in the art. Also, terms that are defined in a general dictionary and that are used in the following description should be construed as having meanings that are equivalent to meanings used in the related description, and unless expressly described otherwise herein, the terms should not be construed as being ideal or excessively formal. Expressions such as “at least one of,” when preceding a list of elements, modify the entire list of elements and do not modify the individual elements of the list.

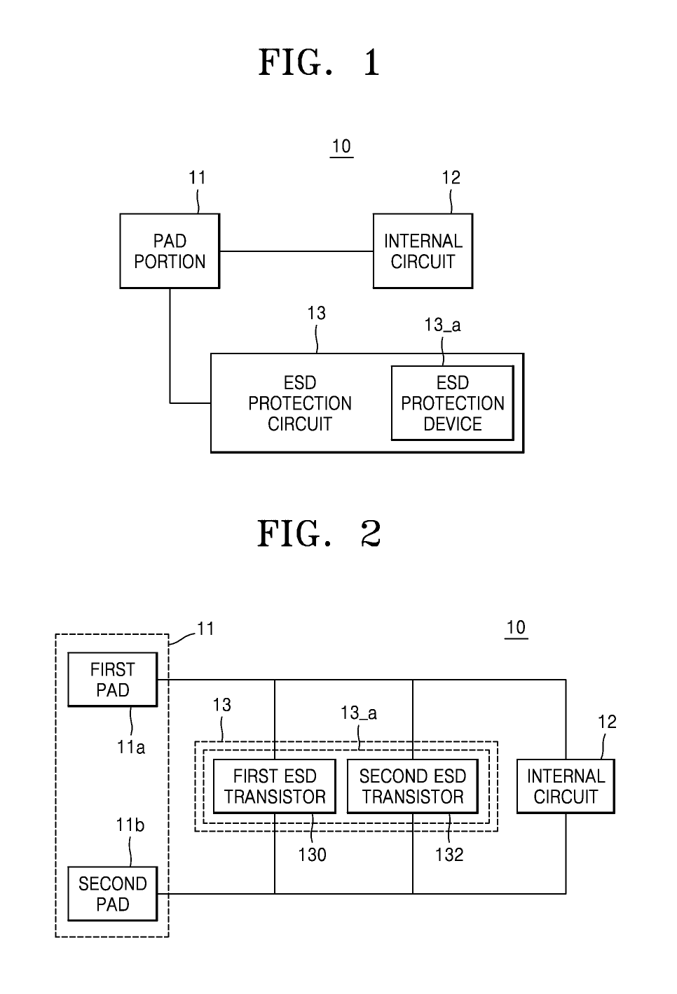

FIG. 1 is a block diagram of a semiconductor device 10, according to an exemplary embodiment of the inventive concept.

Referring to FIG. 1, the semiconductor device 10 includes a pad (or terminal) portion 11, an internal circuit 12, and an electrostatic discharge (ESD) protection circuit 13. The ESD protection circuit 13 may include at least one ESD protection device 13_{—}a. The ESD protection device 13_{—}a may include at least one parasitic transistor. The pad portion 11 may include an input/output (I/O) pad to which a signal that is input from the outside or output to the outside is applied, a power supply voltage pad to which a power supply voltage is applied, and a ground voltage pad to which a ground voltage is applied. The I/O pad, power supply voltage pad, and ground voltage pad of the pad portion 11 may be electrically connected to the internal circuit 12 and the ESD protection circuit 13. The semiconductor device 10 may be a device performing various functions, for example, a memory device. When the semiconductor device 10 is a memory device, the internal circuit 12 may be a memory controller for controlling memory operations. The internal circuit 12 may include a peripheral circuit of a memory (not shown), and may receive or process a control signal of a memory controller (now shown) and perform a memory control operation. The internal circuit 12 may be a memory including cells for storing data.

The ESD protection circuit 13 may be selectively turned on depending on the inflow of an external surge. The ESD protection circuit 13 may be electrically connected to the pad portion 11 and may include at least one ESD protection device 13_{—}a. The ESD protection device 13_{—}a may prevent a local current concentration effect, and thus, may strengthen a tolerance to ESD. Accordingly, when an ESD operation is performed, the ESD protection circuit 13 is electrically connected to the pad portion 11, and forms a plurality of excessive current paths so that an excessive current, which is greater than a normal current, may be discharged. A detailed configuration of the ESD protection device 13_{—}a will be described later.

FIG. 2 is a block diagram specifically illustrating an ESD protection device 13_{—}a of a semiconductor device 10, according to an exemplary embodiment of the inventive concept.

Referring to FIG. 2, a pad portion 11 may include a first pad 11a and a second pad 11b. The first pad 11a may be at least one of a power supply voltage pad and an I/O pad. The second pad 11b may correspond to a ground supply voltage pad. An ESD protection circuit 13 may include at least one ESD protection device. In FIG. 2, the ESD protection circuit 13 includes only one ESD protection device 13_{—}a as an example. A first ESD protection transistor 130 and a second ESD protection transistor 132 may be included in the ESD protection device 13_{—}a. The first ESD protection transistor 130 and the second ESD protection transistor 132 may be parasitic bipolar junction transistors (BJTs).

When a surge is applied to the first pad 11a, a surge current may occur, and then, may flow through the first and second ESD protection transistors 130 and 132.

The first and second ESD protection transistors 130 and 132 may have the same triggering voltage, and may be turned on at the same time to allow a surge current to flow therethrough at the same time. The second ESD protection transistor 132 may be formed to have a deep well structure to be described below, according to an exemplary embodiment of the inventive concept.

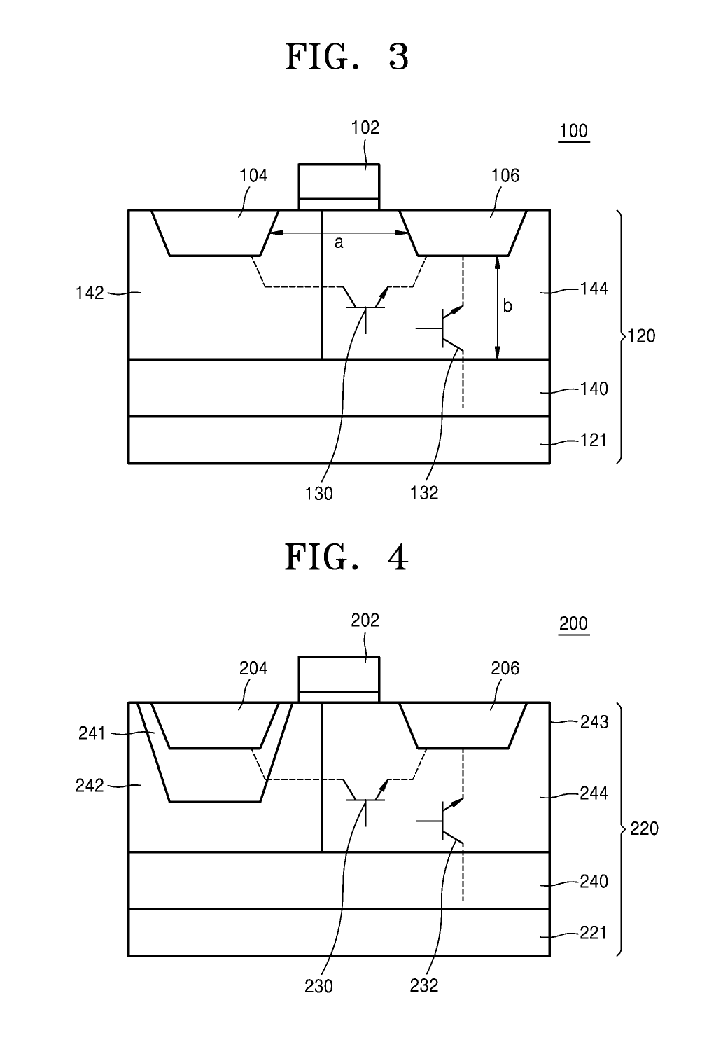

FIG. 3 is a cross-sectional view of an ESD protection device 100, according to an exemplary embodiment of the inventive concept.

Referring to FIG. 3, the ESD protection device 100 includes an N-type deep well 140 formed on a P-type region 121, and also includes an N well 142 and a P well 144 formed on the N-type deep well 140. Although not illustrated in FIG. 3, P-type impurities are implanted to form the P well 144. A gate 102 is formed on a surface of a semiconductor substrate 120, and a drain and a source are formed at both sides of a region under the gate 102. According to an exemplary embodiment, an N+ drain 104 is formed in a portion of the N well 142, and an N+ source 106 is formed in a portion of the P well 142. An impurity doping concentration gradient may satisfy a condition in which P-type region 121<P well 144 and N well 142<P+ region and N+ region. The N+ drain 104 may be connected to at least one selected from an I/O pad and a power supply voltage pad, and the N+ source 106 may be connected to a ground supply voltage pad.

The P well 144 of the ESD protection device 100 is formed in the semiconductor substrate 120 and surrounds at least a region under the gate 102 and the N+ source 106. The N-type deep well 140 is formed in the semiconductor substrate 120, and is positioned under the N well 142 and the P well 144. The ESD protection device 100 having the above-described structure may form a horizontal parasitic BJT 130 and a vertical parasitic BJT 132 when a positive surge is applied to the N+ drain 104 through at least one of the I/O pad and the power supply voltage pad. In this case, the horizontal parasitic BJT 130 may be formed under the gate 102, and include the N+ drain 104 and the N+ source 106 as electrodes. The vertical parasitic BJT 132 may be formed under the N+ source 106, and include the N+ source 106 and a portion of the N-type deep well 140 as electrodes. Accordingly, the horizontal parasitic BJT 130 and the vertical parasitic BJT 132 operate as NPN BJTs. However, the position of the horizontal parasitic BJT 130 and the position of the vertical parasitic BJT 132 may be changed according to another exemplary embodiment.

The N well 142 is formed by implanting N-type impurities into the semiconductor substrate 120, and the N+ drain 104 is formed by additionally implanting N-type impurities into a portion of the N well 142. A doping concentration of the N well 142 may be lower than that of the N+ drain 104. Furthermore, the doping concentration of the N well 142 may gradually decrease toward the bottom of the N well 142. Thus, a plurality of surge current paths may be generated through an area in which the N well 142 is formed. This structure may compensate for a shortcoming that a local current concentration effect is worsened since a sidewall portion of the N+ drain 104 is narrow in area compared to a lower surface of the N+ drain 104 and has a curved surface. That is, since the N well 142 has a sidewall portion and a lower surface which have relatively large areas and are not curved, an excessive current flowing through the ESD protection device 100 may be dispersed. Accordingly, Joule heating occurring due to a concentration of a current may be prevented, and thus, the degrading of characteristics of the ESD protection device 100 may be prevented, thereby strengthening the tolerance of the ESD protection device 100.

The N well 142 and the N-type deep well 140 may be formed to contact each other, and may also be formed in a single body. Accordingly, an excessive current flowing through the N well 142 may be flow through the N-type deep well 140. That is, a new current path is formed, and thus, a concentration of current may be prevented. In addition, a holding voltage may be increased by setting an operational bias point of a parasitic BJT in the ESD protection device 100 via the N-type deep well 140 so that the parasitic BJT may continuously operate and thus excessive current may smoothly flow.

A distance a between the N+ drain 104 and the N+ source 106 and a distance b between the N-type deep well 140 and the N+ source 106 may be adjusted such that at least two parasitic BJTs of the ESD protection device 100 substantially have the same triggering voltage to simultaneously operate the at least two parasitic BJTs. In this case, the distance a between the N+ drain 104 and the N+ source 106 may be determined such that a problem of an operation voltage and a punch through do not occur. That is, the distance a between the N+ drain 104 and the N+ source 106 may be determined to be a specific value or more in which a problem of an operation voltage and a punch through do not occur, and the distance b between the N-type deep well 140 and the N+ source 106 may also be determined in the same manner. According to an exemplary embodiment, the distance b between the N-type deep well 140 and the N+ source 106 may be set to be the same as or similar (within a specific error range) to the distance a between the N+ drain 104 and the N+ source 106 so that a triggering voltage of the horizontal parasitic BJT 130 and a triggering voltage of the vertical parasitic BJT 132 are the same as or similar to each other. Thus, during an ESD operation, the horizontal parasitic BJT 130 and the vertical parasitic BJT 132 may allow an excessive current to flow therethrough at the same time, and thus, the amount of the excessive current which the ESD protection device 100 may endure may instantaneously increase.

An operation of the ESD protection device 100 is described below. When a positive surge is applied to the N+ drain 104, an avalanche breakdown occurs between the N+ drain 104 and the P well 144, and thus, a potential of the P well 144 rises. Due to this, a forward bias is applied between an emitter and a base of the horizontal parasitic BJT 130 and between an emitter and a base of the vertical parasitic BJT 132, and thus, the horizontal and vertical parasitic BJTs 130 and 132 are turned on. A surge voltage applied to the N+ drain 104 when the horizontal and vertical parasitic BJTs 130 and 132 are turned on is referred to as a triggering voltage Vt1. In the ESD protection device 100, the horizontal parasitic BJT 130 and the vertical parasitic BJT 132 may be simultaneously turned on in response to the triggering voltage Vt1. Accordingly, an excessive current occurring due to a surge flows to the N+ source 106, connected to the ground voltage pad, through the turned-on horizontal and vertical parasitic BJTs 130 and 132, and thus, the surge applied to the N+ drain 104 is discharged. In the horizontal parasitic BJT 130, a surge current may flow through a first path including a first electrode (i.e., the N+ drain 104) and a second electrode (i.e., the N+ source 106). In the vertical parasitic BJT 132, the surge current may flow through a second path including a third electrode (i.e., the N-type deep well 140) and a fourth electrode (i.e., the N+ source 106).

According to an exemplary embodiment of the inventive concept, the triggering voltage Vt1 may be lowered by making the impurity doping concentration of the P well 144 higher than that of the P-type region 121 so that an avalanche breakdown between the N+ drain 104 and the P well 144 may more quickly occur. As a result, the horizontal parasitic BJT 130 and the vertical parasitic BJT 132 may be simultaneously turned on. The inventive concept is not limited to the current embodiment. For example, an N-type may be changed to a P-type, and a P-type may be changed to an N-type.

FIG. 4 is a cross-sectional view of an ESD protection device 200, according to another exemplary embodiment of the inventive concept.

Referring to FIG. 4, the ESD protection device 200 includes an N-type deep well 240 formed on a P-type region 221, and also includes a first N well 242 and a P well 244, formed on the N-type deep well 240. A gate 202 is formed on a surface of a semiconductor substrate 220, and a second N well 241 is further formed in a portion of the first N well 242. An N+ drain 204 is formed in a portion of the second N well 241 at one side of the gate 202, and an N+ source 206 is formed in a portion of the P well 244 at the other side of the gate 202. An impurity doping concentration gradient may satisfy a condition in which P-type region 221<P well 244 and first N well 242<second N well 241<P+ region and N+ region. The impurity doping concentration gradient is only an example, and may be changed. The N+ drain 204 may be connected to at least one selected from an I/O pad and a power supply voltage pad, and the N+ source 206 may be connected to a ground supply voltage pad.

In the ESD protection device 200 having the above-described structure, a horizontal parasitic BJT 230 and a vertical parasitic BJT 232 may be formed when a positive surge is applied to the N+ drain 104 through at least one of the I/O pad and the power supply voltage pad. In this case, the horizontal parasitic BJT 230 may be formed under the gate 202, and include the N+ drain 204 and the N+ source 206 as electrodes. The vertical parasitic BJT 232 may be formed under the N+ source 206, and include the N+ source 206 and a portion of the N-type deep well 240 as electrodes. Accordingly, the horizontal parasitic BJT 230 and the vertical parasitic BJT 232 operate as NPN BJTs. In this case, an operating voltage of the horizontal parasitic BJT 230 may be set to be relatively high since the second N well 241 is further formed in a portion of the first N well 242. That is, since the second N well 241 is further formed in a portion of the first N well 242, an operation voltage of the horizontal parasitic BJT 230 may be set to be higher than that of the vertical parasitic BJT 232, and an excessive current flowing through the horizontal parasitic BJT 230 may be reduced, and thus, a holding voltage of the vertical parasitic BJT 232 may be increased. When the holding voltage is increased, the vertical parasitic BJT 232 is turned on to allow an excessive current to flow therethrough. In addition, as described with reference to FIG. 2, a concentration of a current may be suppressed by increasing an area, through which an excessive current may flow, by using the structure of the first N well 242, and thus, device degradation that occurs due to heat generation may be prevented. According to an exemplary embodiment, a second P well (not shown) may be formed in a portion of the P well 244. In this case, an operating voltage of the vertical parasitic BJT 232 may be set to be relatively high so that the horizontal and vertical parasitic BJTs 230 and 232 may be turned on only when a surge having a certain size or more occurs. The inventive concept is not limited to the current embodiment, and an N-type may be changed to a P-type and a P-type may be changed to an N-type.

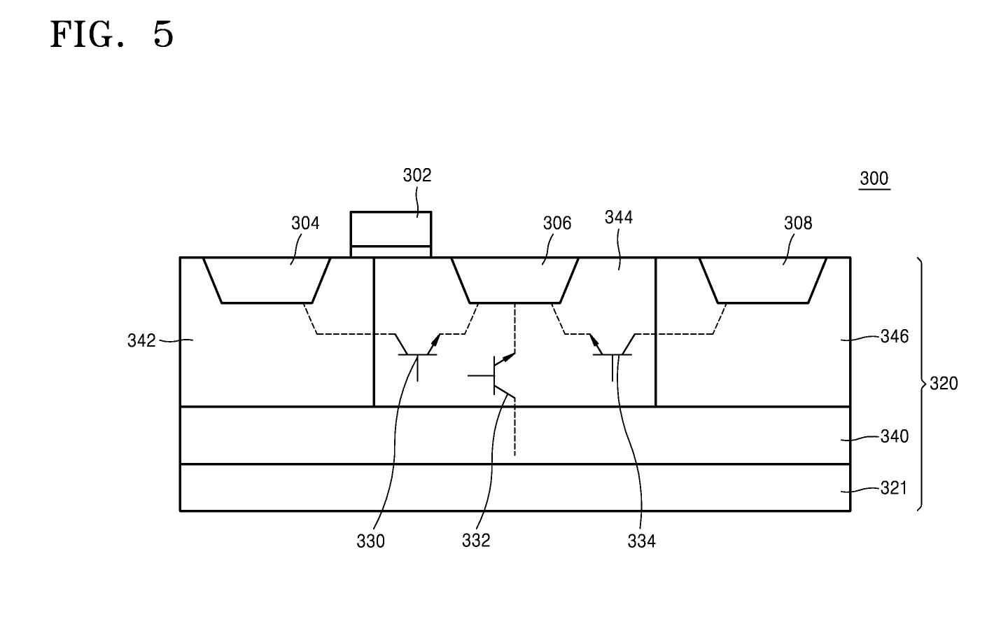

FIG. 5 is a cross-sectional view of an ESD protection device 300, according to another exemplary embodiment of the inventive concept.

Referring to FIG. 5, the ESD protection device 300 may further include a structure in which an N-type deep well 340 is formed on a P-type region 321, a second N well 346 in addition to a first N well 342 is formed on the N-type deep well 340, and a second drain 308, which is an N+ drain, is formed in a portion of the second N well 346, compared to the configuration of the ESD protection device 100 shown in FIG. 3. A first drain 304 or a second drain 308 may be electrically connected to at least one of an I/O pad and a power supply voltage pad, and a first horizontal parasitic BJT 330, a vertical parasitic BJT 332, and a second horizontal parasitic BJT 334 may be formed when a positive surge is applied to at least one of the first drain 304 and the second drain 308. The first horizontal parasitic BJT 330 may be formed under a gate 302, the vertical parasitic BJT 332 may be formed under a source 306 formed in a portion of a P well 344, and the second horizontal parasitic BJT 334 may be formed between the second drain 308 and the source 306. Accordingly, the first horizontal parasitic BJT 330, the vertical parasitic BJT 332, and the second horizontal parasitic BJT 334, all of which are formed in the P well 344, operate as NPN BJTs. However, the position of the first horizontal parasitic BJT 330, the position of the vertical parasitic BJT 332, and the position of the second horizontal parasitic BJT 334 may be changed, according to other exemplary embodiments.

In the first horizontal parasitic BJT 330, a surge current may flow through a first path including the first drain 304, corresponding to a first electrode, and the source 306 corresponding to a second electrode. In the vertical parasitic BJT 332, the surge current may flow through a second path including a third electrode formed in the N-type deep well 340 and a fourth electrode formed in the source 306. In the second horizontal parasitic BJT 334, the surge current may flow through a third path including a fifth electrode formed in the drain 308 and a sixth electrode formed in the source 306. As the number of paths through which a surge current flows increases compared to the embodiment of FIG. 3, the tolerance of the ESD protection device 300 may be strengthened.

According to exemplary an embodiment of the inventive concept, the second drain 308 may be formed to be surrounded by the N well 346, and a doping concentration of the second N well 346 may be lower than that of the second drain 104. Furthermore, the doping concentration of the second N well 346 may gradually decrease toward the bottom of the second N well 346. Thus, a path of an excessive current through the entire area of the second N well 346 may be formed, and thus, this structure may compensate for a shortcoming that a local current concentration effect is aggravated since a sidewall portion of the second drain 308 is narrow in area compared to a lower surface of the second drain 308 and has a curved surface. That is, since the second N well 346 has a sidewall portion and a lower surface, which have relatively large areas and are not curved, an excessive current flowing through the ESD protection device 300 may be dispersed. Accordingly, Joule heating occurring due to a concentration of a current may be prevented, and thus, the degrading of characteristics of the ESD protection device 300 may be prevented, thereby strengthening the tolerance of the ESD protection device 300. In addition, since the ESD protection device 300 further includes the second drain 308 and the second N well 346, at least one additional parasitic BJT may be formed, and thus, a much more excessive current may flow. The inventive concept is not limited to the current embodiment. For example, an N-type may be changed to a P-type, and a P-type may be changed to an N-type.

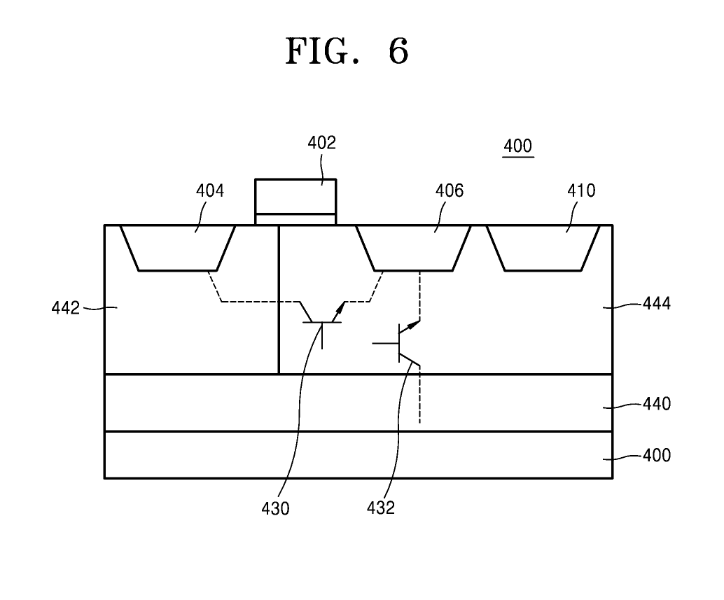

FIG. 6 is a cross-sectional view of an ESD protection device 400, according to another exemplary embodiment.

Referring to FIG. 6, the ESD protection device 400 may further include a structure in which a second source 410, which is a P+ source, is formed in a portion of a P well 444, compared to the configuration of the ESD protection device 100 shown in FIG. 3. The second source 410 and a source 406 may be electrically connected to a ground voltage pad during an ESD operation. The second source 410 may prevent the outflow of an excessive current during the ESD operation, and thus, may reduce an influence on an external device, which may occur due to an excessive current. In addition, since a path for the flow of an excessive current may be further formed, the amount of an excessive current which the ESD protection device 400 may endure may be increased. The inventive concept is not limited to the current embodiment. For example, an N-type may be changed to a P-type, and a P-type may be changed to an N-type.

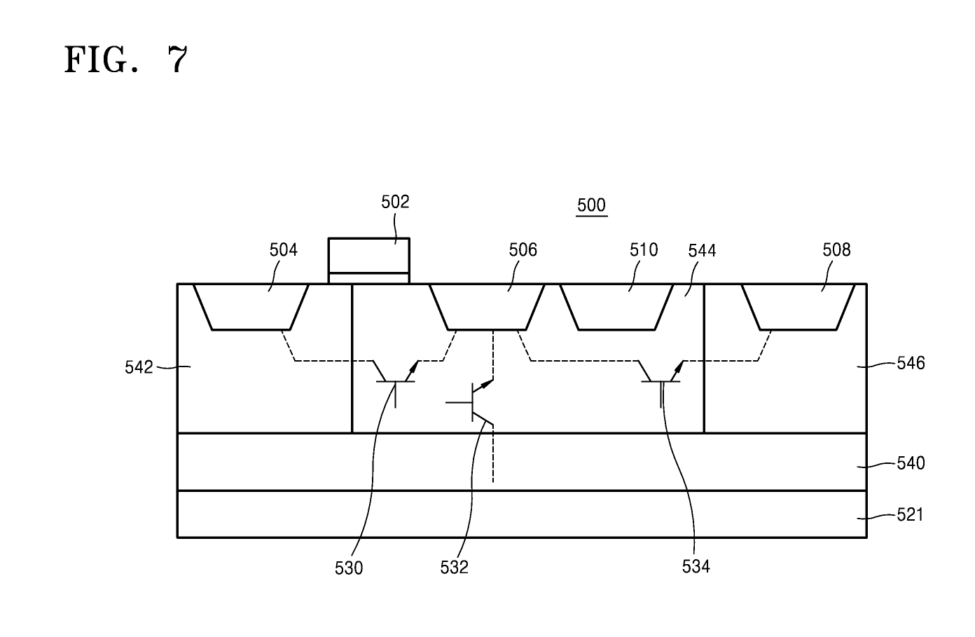

FIG. 7 is a cross-sectional view of an ESD protection device 500, according to another exemplary embodiment of the inventive concept.

Referring to FIG. 7, the configuration of the ESD protection device 300 shown in FIG. 5 and the configuration of the ESD protection device 400 shown in FIG. 6 are used in the ESD protection device 500. Thus, duplicate descriptions are omitted herebelow.

Referring to FIG. 7, the ESD protection device 500 may further include a structure in which an N-type deep well 540 is formed on a P-type region 521, a second N well 546 is formed on the N-type deep well 540, and a second drain 508, which is an N+ drain, is formed in a portion of the second N well 546, compared to the configuration of the ESD protection device 100 shown in FIG. 3. In addition, the ESD protection device 500 may further include a structure in which a second source 510, which is a P+ source, is formed in a portion of the P well 544. Thus, a plurality of parasitic BJTs 530, 532, and 534 that function as surge current paths may be formed to thereby improve the tolerance of the ESD protection device 500.

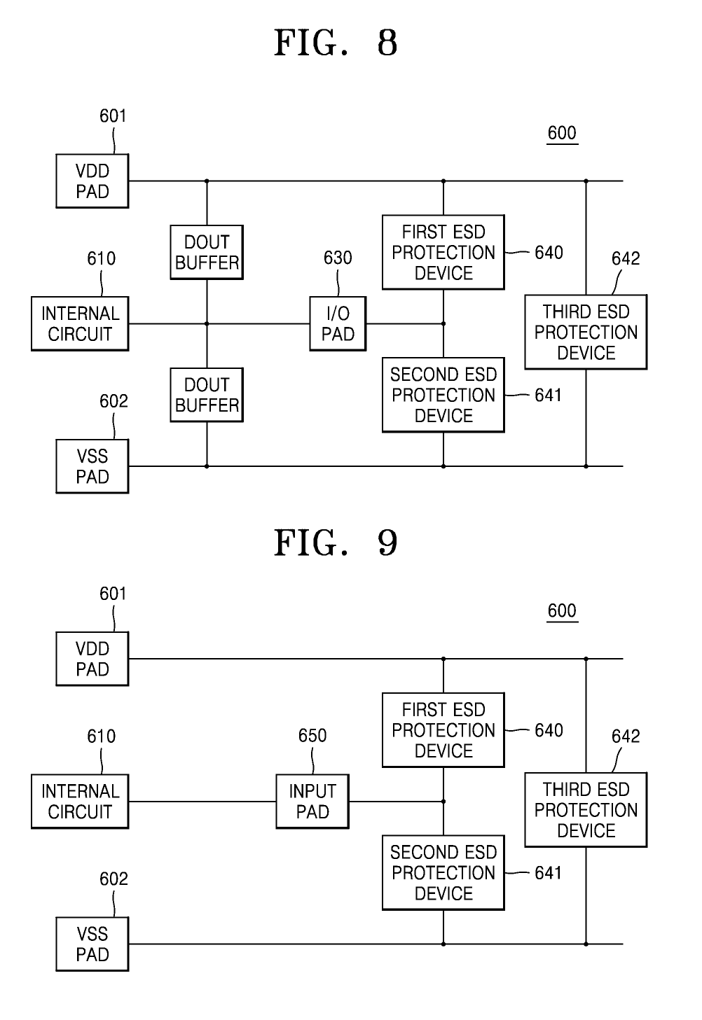

FIG. 8 is a block diagram of a semiconductor internal circuit 600 using an ESD protection device, according to an exemplary embodiment of the inventive concept, and FIG. 9 is a block diagram of a semiconductor internal circuit 600 using an ESD protection device, according to another exemplary embodiment of the inventive concept.

Referring to FIG. 8, an I/O pad 630 may be electrically connected to an internal circuit 610, a first ESD protection device 640, and a second ESD protection device 641. A third ESD protection device 642 may be electrically connected to a power supply voltage (VDD) pad 601 and a ground voltage (VSS) pad 602. An input signal applied to a semiconductor device including the semiconductor internal circuit 600 or an output signal output from the inside of the semiconductor device may be applied to the I/O pad 630. When a surge other than the input signal and the output signal is applied to the I/O pad 630, a surge current does not flow to the internal circuit 610, and transistors formed in the first and second ESD protection devices 640 and 641 may be turned on, and thus, the surge current may flow through the transistors. Furthermore, when a surge is applied to the VDD pad 601, a transistor formed in the third ESD protection 642 may be turned on, and thus, a surge current may flow through the transistor.

Referring to FIG. 9, an input pad 650 may be electrically connected to an internal circuit 610, a first ESD protection device 640, and a second ESD protection device 641. A third ESD protection device 642 may be electrically connected to a power supply voltage (VDD) pad 601 and a ground voltage (VSS) pad 602. An input signal applied to a semiconductor device including the semiconductor internal circuit 600 may be applied to the input pad 650. When a surge other than the input signal is applied to the input pad 650, a surge current does not flow to the internal circuit 610, and transistors formed in the first and second ESD protection devices 640 and 641 may be turned on, and thus, the surge current may flow through the transistors. Furthermore, when a surge is applied to the VDD pad 601, a transistor formed in the third ESD protection 642 may be turned on, and thus, a surge current may flow through the transistor.

The first through third ESD protection devices 640, 641, and 642 of FIGS. 8 and 9 have configurations described above and do not have influence on a normal operation of the semiconductor internal circuit 600 since they are turned off during the normal operation of the semiconductor internal circuit 600. However, when a surge is applied to the I/O pad 630 (or the input pad 650) and the VDD pad 601, the first through third ESD protection devices 640, 641, and 642 enter an ESD operation mode and provide electrostatic discharge paths, i.e., excessive current paths, to perform a function for protecting the semiconductor internal circuit 600 from an excessive current occurring due to the surge. The first through third ESD protection devices 640, 641, and 642 may be metal oxide semiconductor (MOS) transistors, diodes, or silicon controlled rectifiers (SCRs).

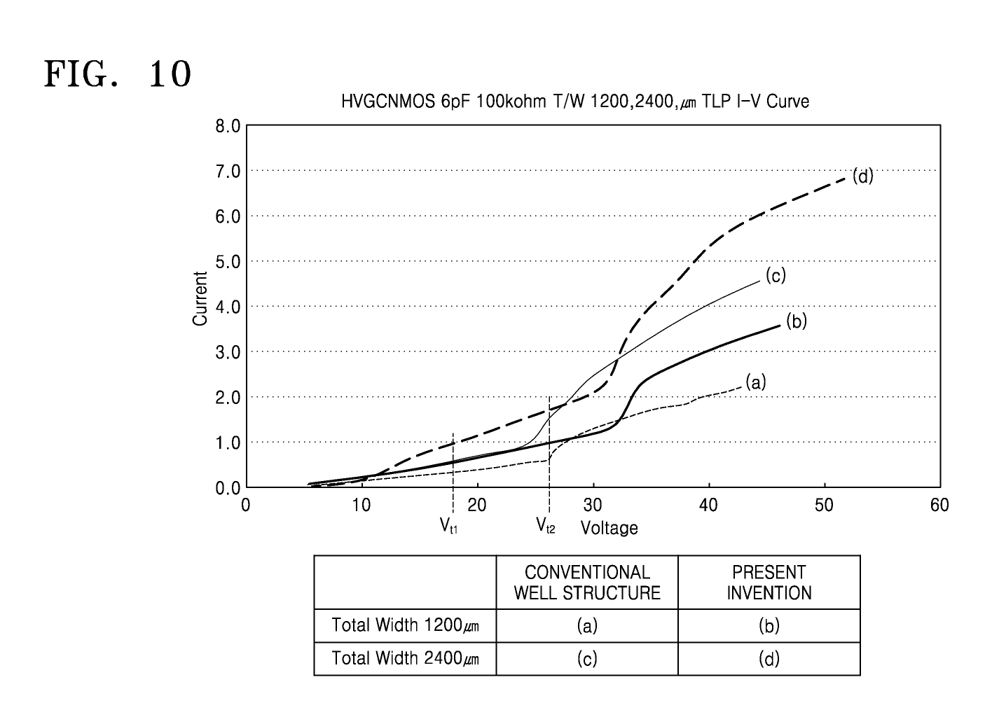

FIG. 10 is a graph showing a comparison between current-voltage characteristics (b) and (d) of ESD protection devices according to exemplary embodiments of the inventive concept, and current-voltage characteristics (a) and (c) of related-art ESD protection devices.

The related-art ESD protection devices having the current-voltage characteristics (a) and (c) have a configuration for lowering a triggering voltage of a parasitic BJT formed therein, and thus, a triggering voltage Vt1 of the related art ESD protection devices are formed between 10 volt and 20 volt. On the other hand, since the ESD protection devices according to the exemplary embodiments, which have the current-voltage characteristics (b) and (d), do not have a configuration for lowering a triggering voltage of a parasitic BJT formed therein, a triggering voltage Vt2 of the ESD protection devices according to the exemplary embodiments are formed between 20 volt and 30 volt. In terms of the amount of an excessive current which the ESD protection devices may endure, the amount of a maximum excessive current that may flow through the ESD protection device having the current-voltage characteristics (b) is greater than the amount of maximum excessive current that may flow through the related-art ESD protection device having the current-voltage characteristics (a). In the same manner, the amount of a maximum excessive current that may flow through the ESD protection device having the current-voltage characteristics (d) is greater than the amount of a maximum excessive current that may flow through the related-art ESD protection device having the current-voltage characteristics (c). This means that the ESD protection devices according to the exemplary embodiments of the inventive concept may suppress device degradation occurring due to heat generation by preventing a current concentration phenomenon and may endure a large amount of an excessive current by securing a plurality of excessive current paths.

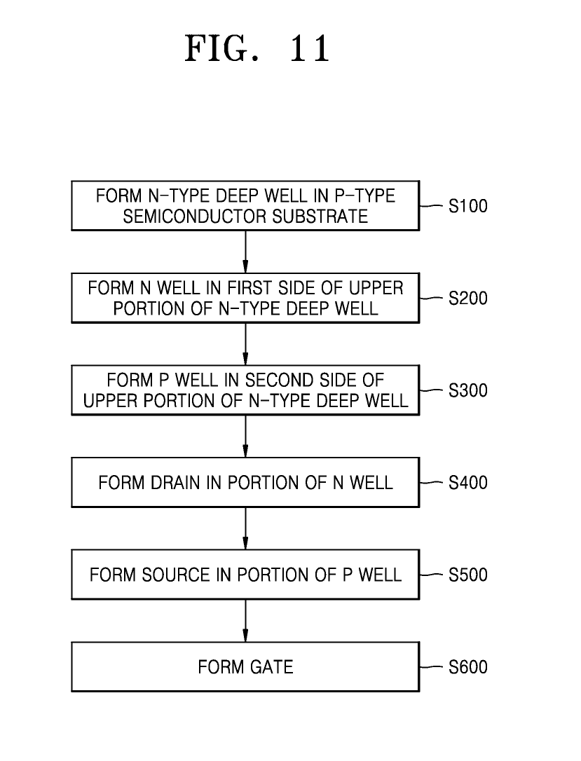

FIG. 11 is a flowchart of a method of forming an ESD protection device, according to an exemplary embodiment of the inventive concept.

Referring to FIG. 11, an N-type deep well may be formed in a P-type semiconductor substrate (S 100). N-type impurities may be implanted into the P-type semiconductor substrate to form the N-type deep well in a portion of the P-type semiconductor substrate. After the N-type deep well is formed, an N well may be formed by implanting N-type impurities into a first side of an upper portion of the N-type deep well (S200). The N well may be formed to contact the N-type deep well, and the doping concentration of the N well may gradually decrease toward the bottom of the N well. After the N well is formed in the first side of the upper portion of the N-type deep well, a P well may be formed by implanting P-type impurities into a second side of the upper portion of the N-type deep well (S300). The second side may be in an opposite direction to the first side, and the doping concentration of the P well may gradually decrease toward the bottom of the P well. Next, N+ impurities may be implanted into a portion of the N well to form a drain (S400), and P+ impurities may be implanted into a portion of the P well to form a source (S500). The concentration of the N+ impurities may be higher than the doping concentration of the N well, and the concentration of the P+ impurities may be higher than the doping concentration of the P well. Next, a gate may be formed (S600). When forming the source and the drain, a distance between the source and the drain may have a first interval, and a distance between the deep well and the source may have a second interval. The first interval and the second interval may be adjusted such that triggering voltages of two or more transistors in the ESD protection device are equal to each other. In this case, the two or more transistors may be simultaneously turned on by the same triggering voltage to allow a surge current to flow therethrough.

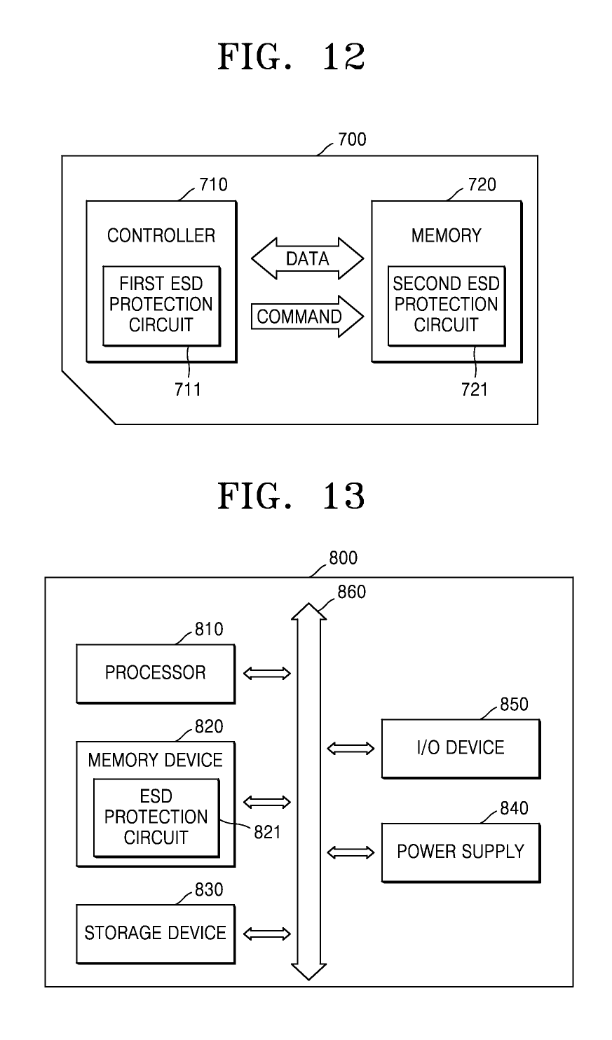

FIG. 12 is a block diagram of a memory card 700 including a semiconductor integrated circuit, according to an exemplary embodiment of the inventive concept.

Referring to FIG. 12, a controller 710 and a memory 720 may be arranged in the memory card 700 to exchange electrical signals. For example, when the controller 710 transmits an instruction to the memory 720, the memory 720 may perform a read operation or a write operation.

The controller 710 and the memory 720 each may include a semiconductor integrated circuit according to any one of the above embodiments of the inventive concept. Specifically, a semiconductor integrated circuit included in the controller 710 may include a first ESD protection circuit 711 including any one of the ESD protection devices of FIGS. 3 through 7, and a semiconductor integrated circuit included in the memory 720 may include a second ESD protection circuit 721 including any one of the ESD protection devices of FIGS. 3 through 7. One or more pads may be disposed in the controller 710, and the first ESD protection circuit 711 may discharge a surge that is input through the one or more pads disposed in the controller 710. In addition, one or more pads may be disposed in the memory 720, and the second ESD protection circuit 721 may discharge a surge that is input through the one or more pads disposed in the memory 720.

The memory card 700 may be used in memory apparatuses such as various types of cards, e.g., a memory stick card, a smart media (SM) card, a secure digital (SD) card, a mini SD card, and a multi-media card (MMC).

FIG. 13 is a block diagram of a computing system 800 including a semiconductor integrated circuit, according to an exemplary embodiment of the inventive concept.

Referring to FIG. 13, the computing system 800 may include a processor 810, a memory device 820, a storage device 830, a power supply 840, an I/O device 850, and a bus 860. Although not shown in FIG. 13, the computing system 800 may further include ports for communicating with a video card, a sound card, a memory card, and a USB device, or with other electronic devices.

The processor 810, the memory device 820, the storage device 830, the power supply 840, and the I/O device 850 each may include a semiconductor integrated circuit according to any one of the above embodiments of the inventive concept. Specifically, each of semiconductor integrated circuits included in the processor 810, memory device 820, storage device 830, power supply 840, and I/O device 850 may include an ESD protection circuit 821, which includes any one of the ESD protection devices of FIGS. 3 through 7, and one or more pads. The ESD protection circuit 821 may discharge a surge that is input through the one or more pads.

The processor 810 may perform specific calculations or tasks. According to an exemplary embodiment, the processor 810 may be a microprocessor or a central processing unit (CPU). The processor 810 may communicate with the memory device 820, the storage device 830, and the I/O device 850 via the bus 860, such as an address bus, a control bus, or a data bus. According to an exemplary embodiment, the processor 810 may also be connected to an extended bus, such as a peripheral component interconnect (PCI) bus.

The memory device 820 may store data required for the operation of the computing system 800. For example, the memory device 820 may be dynamic random-access memory (DRAM), mobile DRAM, static RAM (SRAM), phase-change RAM (PRAM), ferroelectric RAM (FRAM), resistive RAM (RRAM), and/or magnetoresistive RAM (MRAM). The storage device 830 may include a solid state drive, a hard disk drive, a compact disc read-only memory (CD-ROM), etc.

The I/O device 850 may include an input unit, such as a keyboard, a keypad, or mouse, and an output unit, such as a printer or a display. The power supply 840 may supply an operating voltage required for the operation of the computing system 800.

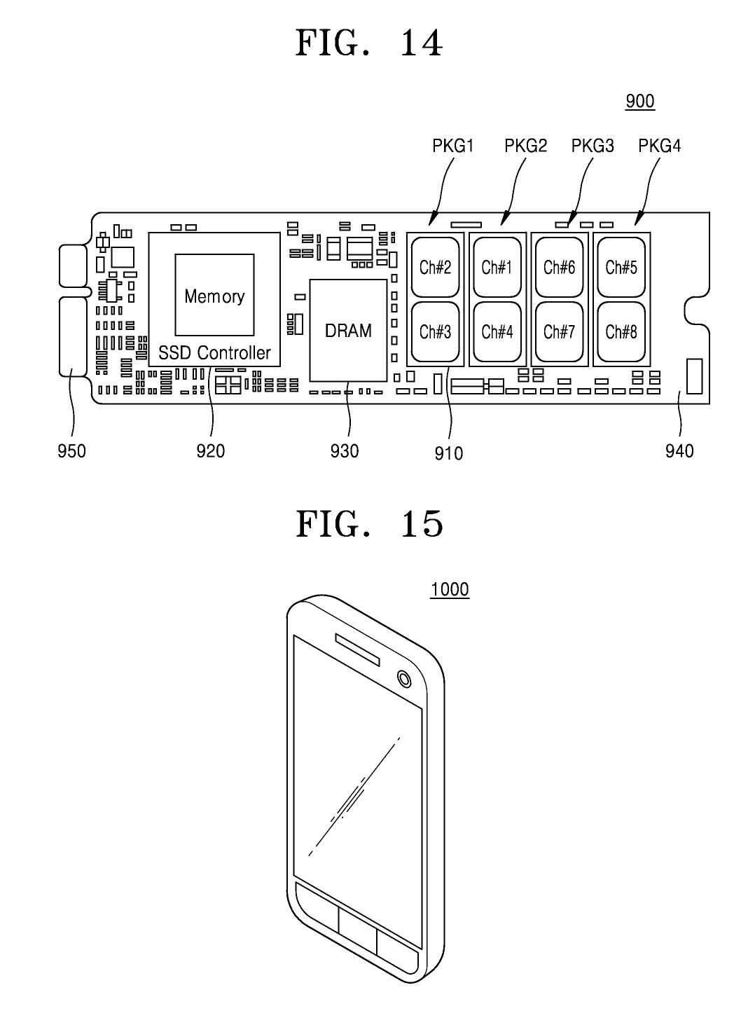

FIG. 14 is a top view of a solid state drive (SSD) device 900 to which a semiconductor package, which includes an ESD protection circuit including at least one ESD protection device according to an embodiment of the inventive concept, is applied.

Referring to FIG. 14, the SSD device 900 may include a memory package 910, an SSD controller package 920, DRAM 930, and a main board 940.

The memory package 910, the SSD controller package 920, and the DRAM 930 may include a semiconductor package according to any one of the above embodiments of the inventive concept. As shown in FIG. 14, the memory package 910 may include four memory packages PKG1, PKG2, PKG3, and PKG4. However, the inventive concept is not limited thereto, and the memory package 910 may include more than four memory packages according to a channel support state of the SSD controller package 920. When the memory package 910 is configured with multiple channels, the memory package 910 may include three or less memory packages.

The memory package 910 may include an ESD protection circuit that includes at least one ESD protection device according to an exemplary embodiment of the inventive concept, for example, at least one of the ESD protection devices of FIGS. 3 through 7.

The SSD controller package 920 may include eight channels, and the eight channels may be one-to-one connected to corresponding channels of the four memory packages PKG1, PKG2, PKG3, and PKG4 to thereby control semiconductor chips in the memory package 910.

The SSD controller package 920 may include a program capable of transmitting or receiving signals to or from an external device in a method based on the serial advanced technology attachment (SATA) standard, the parallel advanced technology attachment (PATA) standard, or the small computer system interface (SCSI) standard. The SATA standard may include all SATA-group standards, such as SATA-1, SATA-2, SATA-3, external SATA (e-SATA), and the like. The PATA standard may include all integrated drive electronics (IDE)-group standards, such as IDE, enhanced IDE (E-IDE), and the like.

The SSD controller package 920 may include an ESD protection circuit that includes at least one ESD protection device, according to an exemplary embodiment of the inventive concept, and may further include one or more pads. The ESD protection circuit may discharge a surge that is input through the one or more pads.

The main board 940 may be a printed circuit board (PCB), a flexible PCB, an organic substrate, a ceramic substrate, a tape substrate, or the like. The main board 940 may include, for example, a core board having an upper surface and a lower surface and resin layers respectively formed on the upper surface and the lower surface. The resin layers may be formed in a multi-layer structure, and a signal layer, a ground layer, or a power layer, which forms a wiring pattern, may be interposed in the multi-layer structure. A separate wiring pattern may be formed on the resin layers. In FIG. 14, minute patterns on the main board 940 may indicate wiring patterns or a plurality of passive elements. An interface 950 for communicating with an external device may be formed on one side, e.g., the left side, of the main board 940.

FIG. 15 is a perspective view of an electronic device to which a semiconductor package, which includes an ESD protection circuit including at least one ESD protection device according to an embodiment of the inventive concept, is applied.

FIG. 15 is an example in which a semiconductor package, which includes an ESD protection circuit including at least one ESD protection device according to an embodiment of the inventive concept (for example, at least one of the ESD protection devices of FIGS. 3 through 7), is applied to a mobile phone 1000. Besides, the semiconductor package may be applied to portable laptop computers, MP3 players, navigation systems, SSDs, vehicles, and household appliances.

While the inventive concept has been particularly shown and described with reference to exemplary embodiments thereof, it will be understood that various changes in form and details may be made therein without departing from the spirit and scope of the inventive concept.

What is claimed is:

1. An electrostatic discharge (ESD) protection device comprising:
a semiconductor substrate of a first conductive type;
a gate formed on the semiconductor substrate;
a first well which is disposed at a first side of the substrate under the gate and comprises a first drain of a second conductive type in at least a portion of the first well;
a second well which is disposed at a second side of the substrate under the gate and comprises a first source of the second conductive type in at least a portion of the second well; and
a deep well of the second conductive type, formed under the first and second wells.

2. The ESD protection device of claim 1, wherein the first and second wells are the second and first conductive types, respectively.

3. The ESD protection device of claim 1, wherein the first conductive type is one selected from an N type and a P type, and the second conductive type is the other selected from the N type and the P type.

4. The ESD protection device of claim 1, wherein an impurity doping concentration of the first drain is higher than that of the first well.

5. The ESD protection device of claim 1, wherein an impurity doping concentration of the first source is higher than that of the second well.

6. The ESD protection device of claim 1, further comprising a second drain of the second conductive type, formed in the semiconductor substrate.

7. The ESD protection device of claim 6, wherein the first drain and the second drain are electrically connected to at least one of a power supply voltage pad and an input/output pad.

8. The ESD protection device of claim 6, further comprising a third well of the second conductive type,
wherein the second drain is formed in at least a portion of the third well, and an impurity doping concentration of the second drain is higher than that of the third well.

9. The ESD protection device of claim 1, further comprising a second source of the first conductive type, formed in the semiconductor substrate.

10. The ESD protection device of claim 9, wherein the first source and the second source are electrically connected to a ground voltage pad.

11. The ESD protection device of claim 9, further comprising a third well of the first conductive type,
wherein the second source is formed in at least a portion of the third well, and an impurity doping concentration of the second source is higher than that of the third well.

12. The ESD protection device of claim 1, further comprising:
a first parasitic transistor formed in the semiconductor substrate, the first parasitic transistor comprising the first drain and the first source as electrodes; and
a second parasitic transistor formed in the semiconductor substrate, the second parasitic transistor comprising the first source and the deep well as electrodes,
wherein a distance between the first drain and the first source is a first interval, a first triggering voltage of the first parasitic transistor is set based on the first interval, a distance between the first source and the deep well is a second interval, a second triggering voltage of the second parasitic transistor is set based on the second interval, and the first triggering voltage is substantially equal or equal to the second triggering voltage.

13. A semiconductor device comprising an electrostatic discharge (ESD) protection circuit and an internal circuit, wherein the ESD protection circuit comprises:
a first ESD protection transistor using a first drain of a second conductive type, a first source of the second conductive type, and a first well of the second conductive type, which are formed in a semiconductor substrate of a first conductive type; and
a second ESD protection transistor using the first source, a second well of the first conductive type, and a deep well of the second conductive type.

14. The semiconductor device of claim 13, wherein a first triggering voltage of the first ESD protection transistor is substantially equal or equal to a second triggering voltage of the second ESD protection transistor.

15. The semiconductor device of claim 13, wherein a surge current occurring due to a surge input from the outside flows through a first path and a second path,
wherein the first path comprises the first drain of the first ESD protection transistor as a first electrode and the first source as a second electrode, and the second path comprises the deep well of the second ESD protection transistor as a third electrode and the first source as a fourth electrode.

16. A semiconductor device comprising an electrostatic discharge (ESD) protection device and an internal circuit, wherein the EST protection device comprises:
a first conductive type substrate;
a second conductive type deep well;
at least one first conductive type well and at least one second conductive type well disposed above the second conductive type deep well;
at least one source formed in the at least one first conductive type well, respectively, and at least one drain formed in the at least one second conductive type well, respectively;
an input/output (I/O) terminal which connects the internal circuit and the first and second to input or output a signal from or to the outside of the internal circuit;
a power supply voltage terminal; and
a ground voltage terminal.

17. The semiconductor device of claim 16, wherein the at least one drain is connected to at least one of the I/O terminal and the power supply voltage terminal, and the at least one source is connected to the ground voltage terminal.

18. The semiconductor device of claim 16, wherein one drain of the at least one drain and one source of the at least one source constitute a first parasitic transistor, and the source and the second conductive type deep well constitute a second parasitic transistor,
wherein a distance between the drain and the source is controlled to be substantially equal or equal to a distance between the source and the second conductive type deep well.

19. The semiconductor device of claim 16, wherein an impurity doping concentration in the at least one second conductive type well decreases from a top to a bottom of the at least one second conductive type well, the top being close to the at least one drain and the bottom being close to the second conductive type deep well.

20. The semiconductor device of claim 16, wherein an impurity doping concentration in the at least one first conductive type well is greater than that in the first conductive type substrate.
